(19) United States
(12) Patent Application Publication
(10) Pub. No.: US 2015/0333729 A1
(43) Pub. Date: Nov. 19, 2015

(54) PIEZOELECTRIC PACKAGE

(71) Applicant: SAMSUNG ELECTRO-MECHANICS CO., LTD., Suwon-Si (KR)

(72) Inventor: Woo Jin CHOI, Suwon-Si (KR)

(21) Appl. No.: 14/575,910

(22) Filed: Dec. 18, 2014

(30) Foreign Application Priority Data
May 16, 2014 (KR) 10-2014-0058989

(51) Int. Cl. H03H 9/17; H03H 9/13; H03H 9/10

(52) U.S. Cl. CPC H03H 9/17; H03H 9/10; H03H 9/13

(57) ABSTRACT

Disclosed herein is a piezoelectric package including: a body having a piezoelectric component mounted therein and having a lower surface electrode provided on a bottom surface thereof, the lower surface electrode being electrically connected to the piezoelectric component; a groove part formed on the bottom surface of the body; and a capacitor component provided in the groove part and electrically connected to the piezoelectric component.

This application claims the benefit under 35 U.S.C. Section 119 of Korean Patent Application No. 10-2014-0058989 entitled “Piezoelectric Package” filed on May 16, 2014, which is hereby incorporated by reference in its entirety into this application.

### BACKGROUND

1. Technical Field

The present invention relates to a piezoelectric package, and more particularly, to a piezoelectric package having a capacitor component embedded therein.

2. Description of the Related Art

A piezoelectric package is a part having a piezoelectric component embedded therein, in which quartz made of SiO₂ is manufactured in a thin piece form, and is generally referred to as a quartz vibrator or a quartz oscillator.

The piezoelectric component has an electrode formed on a surface thereof, in which the electrode is made of a conductive material such as Au or Ag. If a voltage is applied to the electrode, stress is added to the electrode by a piezoelectric effect to thereby cause a vibration. The piezoelectric package is configured to output a frequency occurring by a mechanical vibration. Accordingly, the piezoelectric package has been used as a frequency oscillator or a frequency adjustor in various electronic devices including a mobile communications device.

The piezoelectric package according to the related art has been known as a structure in which the piezoelectric component is mounted on a package substrate which is formed in a flat shape of a single layer using a ceramic based material and an external electrode installed on a bottom surface of the package substrate is connected to the piezoelectric component through a conductive line penetrating through the package substrate (for example, see Patent Document 1).

Meanwhile, the piezoelectric package has capacitor components each connected to input and output terminals of the piezoelectric component, in which the capacitor component has certain capacitance to output a frequency having a value which is suitable for usage purpose and is provided on a printed circuit board (PCB) on which the piezoelectric package is mounted independent from the piezoelectric package.

As such, according to the related art, since the piezoelectric package and the capacitor component are separately configured on one main substrate (PCB), a degree of freedom of a circuit design may be decreased.

In addition, since the capacitor component becomes away from the piezoelectric package, particularly, the piezoelectric component, frequency characteristics may be deteriorated by an increase in a length of a signal line and a volume of the PCB may be increased as much as a space occupied by the capacitor component.

### SUMMARY

An object of the present invention is to provide a piezoelectric package capable of reducing a length of a signal line between a piezoelectric component and a capacitor component to thereby improve frequency characteristics by mounting the capacitor component in the piezoelectric package.

According to an exemplary embodiment of the present invention, there is provided a piezoelectric package including: a body having a piezoelectric component mounted therein and having a lower surface electrode provided on a bottom surface thereof, the lower surface electrode being electrically connected to the piezoelectric component; a groove part formed on the bottom surface of the body; and a capacitor component provided in the groove part and electrically connected to the piezoelectric component.

The lower surface electrode may be formed to surround one end portion of the groove part.

The piezoelectric package may further include a ground electrode provided on the bottom surface of the body and electrically connected to the capacitor component.

The ground electrode may be formed to surround the other end portion of the groove part.

The capacitor component may include a pair of external terminals, wherein one of the pair of external terminals may be electrically connected to the lower surface electrode and the other may be electrically connected to the ground electrode.

The body may be configured by a base part, a lid covering an upper surface of the base part, and a bonding part provided at an outside edge part between the base part and the lid.

The base part may be configured by a first base layer having the groove part formed therein and a second base layer including a connection part electrically connecting the piezoelectric component and the capacitor component to each other.

The connection part may include: a first via penetrating through the second base layer; and a first metal pattern having one end exposed to the outside through the groove part to be connected to the capacitor component and the other end connected to the first via.

The first via may penetrate through up to the first base layer and may be connected to the lower surface electrode.

The piezoelectric package may further include a first lead electrode formed across upper and lower surfaces and a side surface of the first base layer and having one end connected to the lower surface electrode and the other end connected to the first via.

The piezoelectric package may further include: a ground electrode provided on the bottom surface of the body and electrically connected to the capacitor component; a second metal pattern provided on a lower surface of the second base layer and having one end exposed to the outside through the groove part to be connected to the capacitor component; and a second lead electrode formed across upper and lower surfaces and a side surface of the first base layer and having one end connected to the ground electrode and the other end connected to the second metal pattern.

The piezoelectric package may further include: a ground electrode provided on the bottom surface of the body and electrically connected to the capacitor component; a second metal pattern provided on a lower surface of the second base layer and having one end exposed to the outside through the groove part to be connected to the capacitor component; and a second via penetrating through the first base layer and having one end connected to the ground electrode and the other end connected to the second metal pattern.

According to another exemplary embodiment of the present invention, there is provided a piezoelectric package including: a body having a piezoelectric component mounted therein and having a first lower surface electrode and a second lower surface electrode provided on a bottom surface thereof, the first lower surface electrode being electrically connected to an input terminal of the piezoelectric component and the second lower surface electrode being electrically connected to an output terminal of the piezoelectric component; a first groove part and a second groove part formed on the bottom surface of the body; a first capacitor component provided in the first groove part and electrically connected to the input terminal of the piezoelectric component; and a second capacitor component provided in the second groove part and electrically connected to the output terminal of the piezoelectric component.

The piezoelectric package may further include a first ground electrode provided on the bottom surface of the body and electrically connected to the first capacitor component and a second ground electrode electrically connected to the second capacitor component.

The first and second lower surface electrodes and the first and second ground electrodes may be each provided onto corner portions of the bottom surface of the body.

The first capacitor component may include a pair of external terminals, wherein one of the pair of external terminals may be electrically connected to the first lower surface electrode and the other may be electrically connected to the first ground electrode.

The second capacitor component may include a pair of external terminals, wherein one of the pair of external terminals may be electrically connected to the second lower surface electrode and the other may be electrically connected to the second ground electrode.

The first lower surface electrode and the first ground electrode, or the second lower surface electrode and the second ground electrode may be provided to face each other in a shorter side direction of the body, and the first groove part may be provided between the first lower surface electrode and the first ground electrode or the second groove part may be provided between the second lower surface electrode and the second ground electrode.

The first lower surface electrode and the first ground electrode, or the second lower surface electrode and the second ground electrode may be provided to face each other in a longer side direction of the body, and the first groove part may be provided between the first lower surface electrode and the first ground electrode or the second groove part may be provided between the second lower surface electrode and the second ground electrode.

### BRIEF DESCRIPTION OF THE DRAWINGS

FIG. 1 is a cross-sectional view of a piezoelectric package according to an exemplary embodiment of the present invention;

FIG. 2 is a bottom view of a piezoelectric package according to an exemplary embodiment of the present invention;

FIG. 3 is a view showing another example of lower surface electrodes included in the piezoelectric package according to the exemplary embodiment of the present invention;

FIG. 4 is a view showing a structure in which a first groove part and a second groove part included in the piezoelectric package according to the exemplary embodiment of the present invention are disposed in different directions;

FIG. 5 is a plan view of a lower surface of a second base layer included in the piezoelectric package according to the exemplary embodiment of the present invention when being viewed from the bottom;

FIG. 6 is a cross-sectional view taken along line I-I′ of FIG. 5;

FIG. 7 is a plan view of a lower surface of a second base layer included in a piezoelectric package according to another exemplary embodiment of the present invention when being viewed from the bottom;

FIG. 8 is a cross-sectional view taken along line II-II′ of FIG. 7;

FIG. 9 is a cross-sectional view taken along line III-III′ of FIG. 7; and

FIG. 10 is a circuit diagram of the piezoelectric package according to the exemplary embodiment of the present invention.

### DESCRIPTION OF THE PREFERRED EMBODIMENTS

Various advantages and features of the present invention and methods accomplishing thereof will become apparent from the following description of exemplary embodiments with reference to the accompanying drawings. However, the present invention may be modified in many different forms and it should not be limited to exemplary embodiments set forth herein. These exemplary embodiments may be provided so that this disclosure will be thorough and complete, and will fully convey the scope of the invention to those skilled in the art.

Meanwhile, terms used in the present specification are for explaining the embodiments rather than limiting the present invention. Unless explicitly described to the contrary, a singular form includes a plural form in the present specification. The word “comprises” and/or “comprising” used in the present specification will be understood to imply the inclusion of stated component, steps, operations and/or elements but not the exclusion of any other components, steps, operations and/or elements.

Additionally, components shown in the accompanying drawings are not necessarily shown to scale. For example, sizes of some components shown in the accompanying drawings may be exaggerated as compared with other components in order to assist in the understanding of the exemplary embodiments of the present invention. Meanwhile, throughout the accompanying drawings, the same reference numerals will be used to describe the same components. For simplification and clearness of illustration, a general configuration scheme will be shown in the accompanying drawings, and a detailed description of the feature and the technology well known in the art will be omitted in order to prevent a discussion of exemplary embodiments of the present invention from being unnecessarily obscure.

Hereinafter, a configuration and an acting effect of exemplary embodiments of the present invention will be described in more detail with reference to the accompanying drawings.

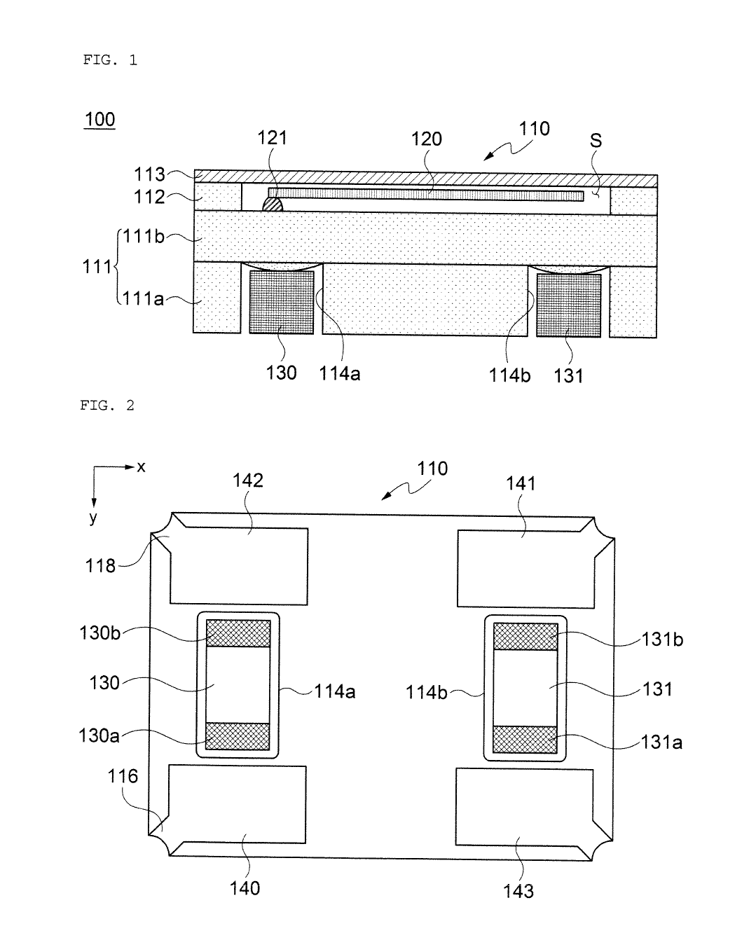

FIG. 1 is a cross-sectional view of a piezoelectric package according to an exemplary embodiment of the present invention.

Referring to FIG. 1, the piezoelectric package 100 according to an exemplary embodiment of the present invention may include a body 110 having a piezoelectric component 120 mounted therein.

The body 110, which is a part made of a ceramic based material, may be particularly configured to include a base part 111 having a rectangular parallelepiped shape, a lid 113 covering an upper surface of the base part 111 and made of a metal material, and a bonding part 112 provided to an outside edge part between the base part 111 and the lid 113.

By the structure as described above, a space part s having a height corresponding to a thickness of the bonding part 112 is generated between the base part 111 and the lid 113 and the piezoelectric component 120 may be disposed in the space part s.

The piezoelectric component may be manufactured by cutting quartz made of SiO₂ into a flat form having a rectangular plane shape and then forming an electrode (not shown) on a surface thereof, and may be applied with a voltage from the outside through a conductive line formed in the body 110.

Specifically, the piezoelectric component 120 may be supported by a conductive adhesive 121 formed on a portion of the base part 111. Accordingly, a lower surface of the piezoelectric component 120 and an upper surface of the base part 111 are not in contact with each other to be spaced apart from each other, such that a vibrating space may be secured.

Groove parts 114a and 114b may be formed in a bottom surface of the body 110, that is, a bottom surface of the base part 111, and capacitor components 130 and 131 which are electrically connected to the piezoelectric component 120 may be mounted in the groove parts 114a and 114b.

For example, the capacitor components 130 and 131 may be a multi-layered ceramic capacitor (MLCC) having a rectangular parallelepiped shape which is formed by stacking several ceramic sheets having an internal electrode formed therein. Accordingly, the groove parts 114a and 114b may also be formed as a space having a rectangular parallelepiped shape. However, the groove parts 114a and 114b may be formed to have a size greater than that of the capacitor components 130 and 131 so that the capacitor components 130 and 131 are easily inserted into the groove parts 114a and 114b.

Since the piezoelectric component 120 outputs a frequency which is generated by a vibration generated by converting electrical energy applied from the outside into mechanical energy, the capacitor components 130 and 131 may be configured to include a first capacitor component 130 which is electrically connected to an input terminal of the piezoelectric component 120 and a second capacitor component 131 which is electrically connected to an output terminal of the piezoelectric component 120.

Similarly, the groove parts 114a and 114b may also be configured to include a first groove part 114a in which the first capacitor component 130 is provided and a second groove part 114b in which the second capacitor component 131 is provided. Electrical connection structures between the piezoelectric component 120 and the capacitor components 130 and 131 will be described below in detail.

FIG. 2 is a bottom view of a piezoelectric package according to an exemplary embodiment of the present invention.

Referring to FIG. 2, lower surface electrodes 140 and 141 may be provided on the bottom surface of the body 110, that is, the bottom surface of the base part 111. The lower surface electrodes 140 and 141 may be electrically connected to an external integrated circuit (IC) when being mounted and transfer the voltage to the piezoelectric component 120 through the conductive line in the body 110.

The lower surface electrodes 140 and 141 may be configured to include a first lower surface electrode 140 which is electrically connected to the input terminal of the piezoelectric component 120 and a second lower surface electrode 141 which is electrically connected to the output terminal of the piezoelectric component 120. Electrical connection structures between the piezoelectric component 120 and the lower surface electrodes 140 and 141 will be described below in detail.

The lower surface electrodes 140 and 141 may be disposed on corner portions of the bottom surface of the body 110. In this case, as shown in FIG. 2, the first lower surface electrode 140 and the second lower surface electrode 141 may be disposed to diagonally face each other, or alternatively, unlike this, may be disposed to face each other in a longer side direction x or a shorter side direction y of the body 110.

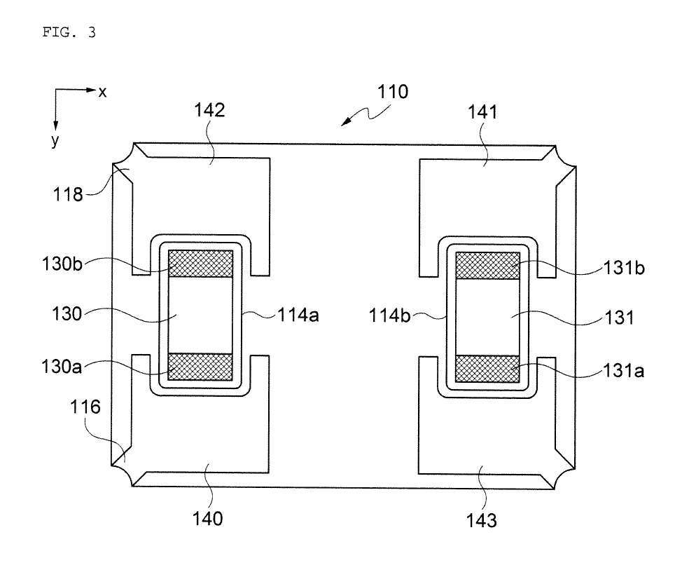

FIG. 3 is a view showing another example of the lower surface electrodes 140 and 141, where the first lower surface electrode 140 may be formed to surround one end portion of the first groove part 114a and the second lower surface electrode 141 may also be similarly formed to surround one end portion of the second groove part 114b. As a result, areas of the lower surface electrodes 140 and 141 are increased, such that a bonded surface between the lower surface electrodes 140 and 141 and the substrate is increased, thereby making it possible to improve connection reliability.

The piezoelectric package 100 according to the exemplary embodiment of the present invention may further include ground electrodes 142 and 143 which are provided on the bottom surface of the body 110, that is, the bottom surface of the base part 111. The ground electrodes 142 and 143 may be electrically connected to the capacitor components 130 and 131 through conductive line formed in the body 110.

Specifically, the ground electrodes 142 and 143 may be configured to include a first ground electrode 142 and a second ground electrode 143, where the first ground electrode 142 may be electrically connected to the first capacitor component 130 and the second ground electrode 143 may be electrically connected to the second capacitor component 131. Electrical connection structures between the capacitor components 130 and 131 and the ground electrodes 142 and 143 will be described below in detail.

The first ground electrode 142 may be formed to surround the other end portion of the first groove part 114a to secure connection reliability with a substrate circuit as shown in FIG. 3 and the second ground electrode 143 may also be formed to surround the other end portion of the second groove part 114b.

The ground electrodes 142 and 143 may be disposed on the corner portions of the bottom surface of the body 110. Here, since the first ground electrode 142 is electrically connected to the first capacitor component 130 together with the first lower surface electrode 140, the first ground electrode 142 and the first lower surface electrode 140 may be disposed to face each other, having the first groove part 114a therebetween.

Similarly, since the second ground electrode 143 is electrically connected to the second capacitor component 131 together with the second lower surface electrode 141, the second ground electrode 143 and the second lower surface electrode 141 may be disposed to face each other, having the second groove part 114b therebetween.

Therefore, in the case in which the first lower surface electrode 140 and the first ground electrode 142 are disposed to face each other in the shorter side direction y of the body 110 as shown in FIG. 2, the first groove part 114a may be disposed to be in parallel with the shorter side direction y of the body 110. Similarly, in the case in which the second lower surface electrode 141 and the second ground electrode 143 are disposed to face each other in the shorter side direction y of the body 110, the second groove part 114b may be disposed to be in parallel with the shorter side direction y of the body 110.

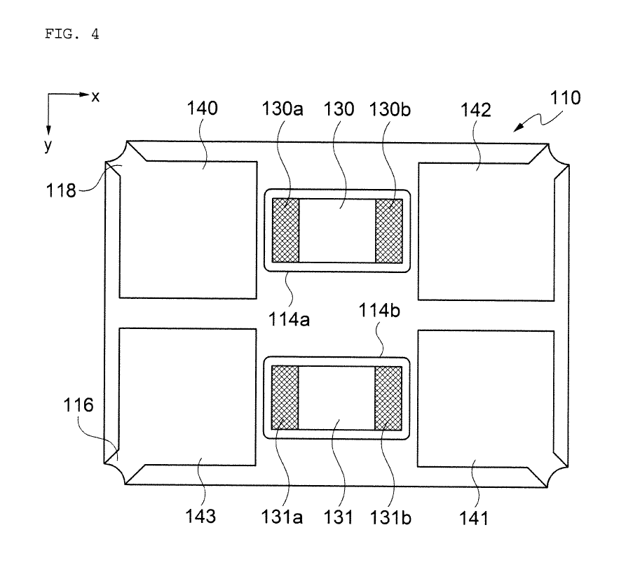

FIG. 4 is a view showing a structure in which a first groove part 114a and a second groove part 114b are disposed in different directions.

Referring to FIG. 4, the first lower surface electrode 140 and the first ground electrode 142 are disposed to face each other in the longer side direction x of the body 110. In this case, the first groove part 114a may be disposed to be in parallel with the longer side direction x of the body 110. Similarly, in the case in which the second lower surface electrode 141 and the second ground electrode 143 are disposed to face each other in the longer side direction x of the body 110, the second groove part 114b may be disposed to be in parallel with the longer side direction x of the body 110.

Hereinafter, connection structures between the piezoelectric component 120 and the capacitor components 130 and 131, between the piezoelectric component 120 and the lower surface electrodes 140 and 141, between the capacitor components 130 and 131 and the lower surface electrodes 140 and 141, and between the piezoelectric component 120 and the ground electrodes 142 and 143 will be described in detail.

First, describing in detail the base part 111 of the body 110 with reference to FIG. 1, the base part 111 may include a first base layer 111a and a second base layer 111b which is bonded on the first base layer 111a.

The first base layer 111a, which is a layer having the groove parts 114a and 114b formed therein, has the capacitor components 130 and 131 inserted thereinto, and the second base layer 111b may include a connecting part electrically connecting the piezoelectric component 120 and the capacitor components 130 and 131 with each other.

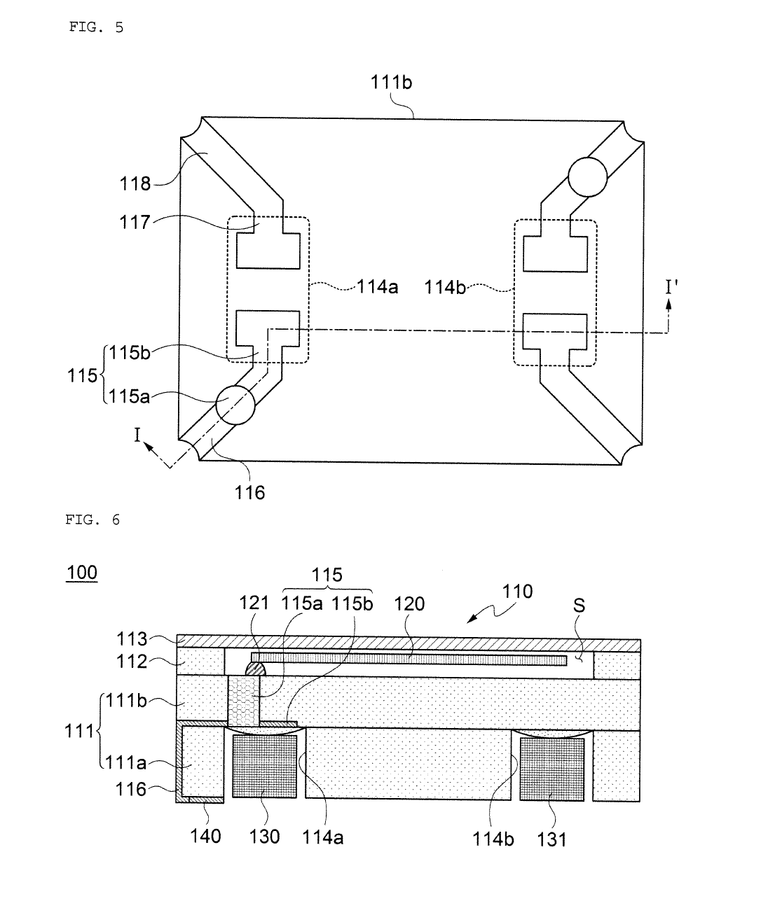

FIG. 5 is a plan view of a lower surface of the second base layer 111b when being viewed from the bottom and FIG. 6 is a cross-sectional view taken along line I-I′ of FIG. 5.

Referring to FIGS. 5 and 6, the connecting part 115 may be configured to include a first via 115a penetrating through the second base layer 111b and a first metal pattern 115b provided on a lower surface of the second base layer 111b.

One end portion (upper end portion) of the first via 115a may be exposed to an upper surface of the second base layer 111b to be connected to the piezoelectric component 120 and the other end portion (lower end portion) thereof may be connected to the first metal pattern 115b. In addition, an end portion of the first metal pattern 115b may be exposed to the outside through the first groove part 114a to be connected to the first capacitor component 130, particularly, to an external terminal 130a of the first capacitor component 130.

By the structure as described above, the first capacitor component 130 may be electrically connected to the piezoelectric component 120 through the first via 115a and the first metal pattern 115b and the second capacitor component 131 may also be electrically connected to the piezoelectric component 120 by the same connection structure.

Here, the end portion of the first metal pattern 115b exposed to the outside through the first groove part 114a may be formed in a pattern of a quadrangular shape having a wider width in order to secure connection reliability with the external terminal 130a of the first capacitor component 130.

The piezoelectric component 120 and the lower surface electrodes 140 and 141 may be electrically connected to each other through the first via 115a and a first lead electrode 116 which is formed across upper and lower surfaces and side surface of the first base layer 111a.

Referring to FIGS. 2, 5, and 6, a first lead electrode 116 (see FIG. 5) formed on the upper surface of the first base layer 111a and a first lead electrode 116 (see FIG. 2) formed on the lower surface of the first base layer 111a may be connected to each other through the side surface of the first base layer 111a having a chamfered shape, where one end of the first lead electrode may be connected to the first lower surface electrode 140 (see FIG. 2) and the other end thereof may be connected to the first via 115a (see FIG. 5). As described above, since one end portion (upper end portion) of the first via 115a is connected to the piezoelectric component 120, the first lower surface electrode 140 may be electrically connected to the piezoelectric component 120 through the first lead electrode 116 and the first via 115a. In addition, the second lower surface electrode 141 may also be electrically connected to the piezoelectric component 120 by the same connection structure as that described above.

Meanwhile, since the first via 115a also is connected to the first metal pattern 115b, the first capacitor component 130 may be electrically connected to the first lower surface electrode 140 by the first metal pattern 115b and the first lead electrode 116 which are connected to each other through the first via 115a. In addition, the second capacitor component 131 may also be electrically connected to the second lower surface electrode 141 by the same connection structure as that described above.

The piezoelectric component 120 and the lower surface electrodes 140 and 141 may be electrically connected to each other by another connection structure (hereinafter, referred to as a second connection structure).

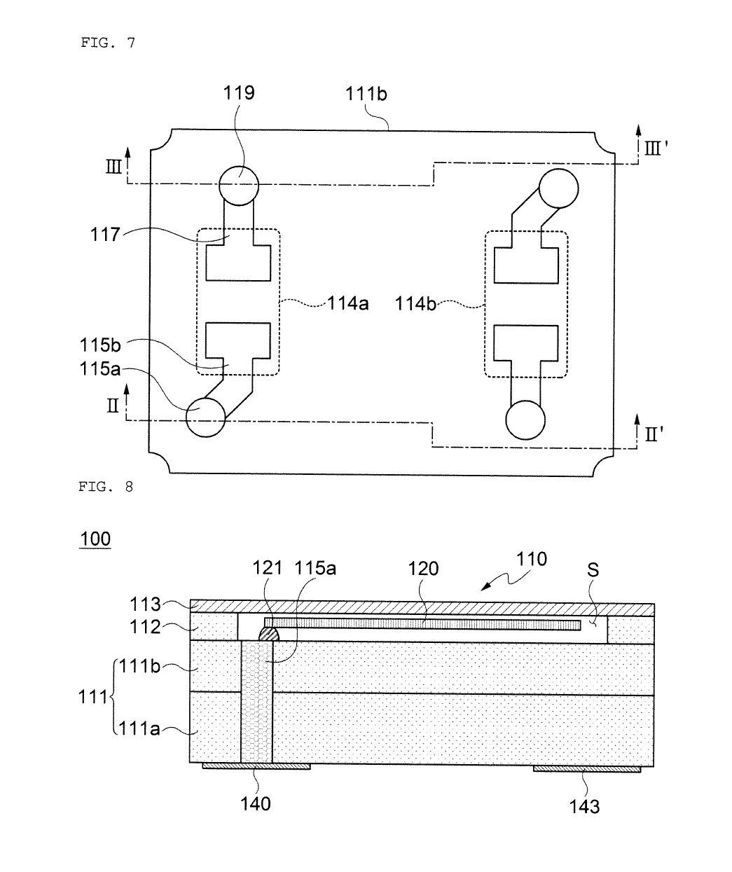

FIG. 7 is a plan view of a lower surface of the second base layer 111b including the second connection structure when being viewed from the bottom and FIG. 8 is a cross-sectional view taken along line II-II′ of FIG. 7.

Referring to FIGS. 7 and 8, the second connection structure does not include the first lead electrode 116. However, as another example, the first via 115a may be formed to penetrate through the first base layer 111a as well as the second base layer 111b. Since both end portions of the first via 115a are directly connected to the piezoelectric component 120 and the first lower surface electrode 140, respectively, the first lower surface electrode 140 may be electrically connected to the piezoelectric component 120 through only the first via 115a. Similarly, the second lower surface electrode 141 may also be electrically connected to the piezoelectric component 120 by the same connection structure as that described above.

Referring back to FIGS. 2 and 5, describing the connection structures between the capacitor components 130 and 131 and the ground electrodes 142 and 143, the first ground electrode 142 may be electrically connected to the first capacitor component 130 through a second metal pattern 117 provided on the lower surface of the second base layer 111b and a second lead electrode 118 formed across the upper and lower surfaces and the side surface of the first base layer 111a.

That is, a second lead electrode 118 (see FIG. 5) formed on the upper surface of the first base layer 111a and a second lead electrode 118 (see FIG. 2) formed on the lower surface of the first base layer 111a may be connected to each other through the side surface of the first base layer 111a having a chamfered shape, where one end of the lead electrode may be connected to the first ground electrode 142 (see FIG. 2) and the other end thereof may be connected to the second metal pattern 117 (see FIG. 5). In addition, an end portion of the second metal pattern 117 may be exposed to the outside through the first groove part 114a to be connected to the first capacitor component 130, particularly, to an external terminal 130b of the first capacitor component 130.

By the structure as described above, the first ground electrode 142 may be electrically connected to the first capacitor component 130 through the second metal pattern 117 and the second lead electrode 118, and the second ground electrode 143 may also be electrically connected to the second capacitor component 131 by the same connection structure as that described above.

Here, the end portion of the second metal pattern 117 exposed to the outside through the first groove part 114a may be formed in a pattern of a quadrangular shape having a wider width in order to secure connection reliability with the external terminal 130b of the first capacitor component 130.

The capacitor components 130 and 131 and the ground electrodes 142 and 143 may be electrically connected to each other by another connection structure (hereinafter, referred to as a third connection structure).

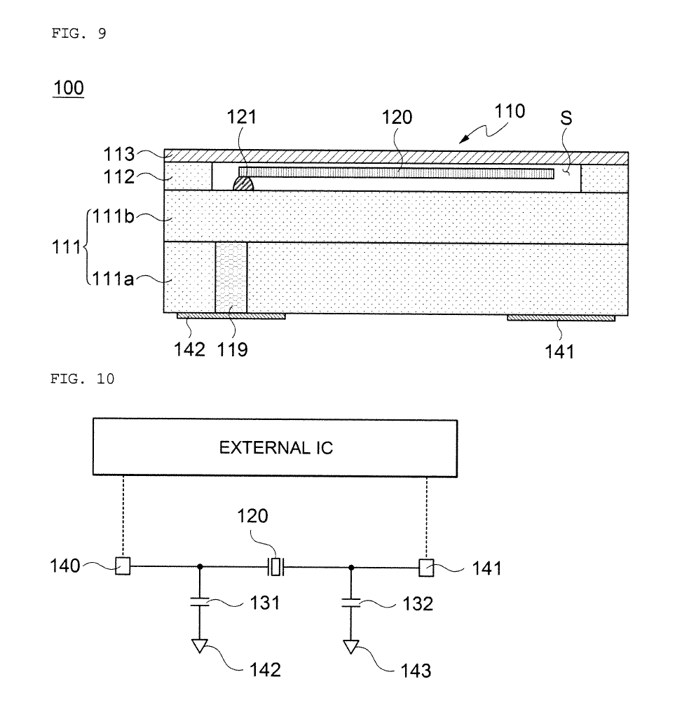

FIG. 7 is a plan view of a lower surface of the second base layer 111b including the third connection structure when being viewed from the bottom and FIG. 9 is a cross-sectional view taken along line III-III′ of FIG. 7.

Referring to FIGS. 7 and 9, the third connection structure does not include the second lead electrode 118. That is, the first ground electrode 142 may be electrically connected to the first capacitor component 130 through the second metal pattern 117 provided on the lower surface of the second base layer 111b and a second via 119 penetrating through the first base layer 111a.

Both end portions of the second via 119 are directly connected to the first ground electrode 142 and the second metal pattern 117, respectively, and an end portion of the second metal pattern 117 may be exposed to the outside through the first groove part 114a to be in contact with the first capacitor component 130, particularly, to the external terminal 130b of the first capacitor component 130.

By the structure as described above, the first ground electrode 142 may be electrically connected to the first capacitor component 130 through the second via 119 and the second metal pattern 117, and the second ground electrode 143 may also be electrically connected to the second capacitor component 131 by the same connection structure as that described above.

FIG. 10 is a circuit diagram of the piezoelectric package according to the exemplary embodiment of the present invention.

According to the connection structures as described above, the input and output terminals of the piezoelectric component 120 may be connected to the first lower surface electrode 140 and the second lower surface electrode 141, respectively. In addition, one end of the first capacitor component 130 may be connected between the input terminal of the piezoelectric component 120 and the first lower surface electrode 140, and the other end thereof may be connected to the first ground electrode 142. Similarly, one end of the second capacitor component 131 may be connected between the output terminal of the piezoelectric component 120 and the second lower surface electrode 141, and the other end thereof may be connected to the second ground electrode 143.

The piezoelectric component 120 converts electrical energy (voltage) input from the first lower surface electrode 140 into mechanical energy to thereby output a frequency generated by vibration toward the external IC through the first lower surface electrode 140.

Here, in order to enable the frequency having a value which is suitable for a usage purpose to be output, the capacitor component having certain capacitance may be used. In this case, in the piezoelectric package according to the present invention, the capacitor component for adjusting the frequency may be provided in the groove parts 114a and 114b of the body and may be electrically connected to the respective configurations in the package by the connection structure as described above.

As a result, the piezoelectric package according to the exemplary embodiment of the present invention may reduce a length of the signal line between the piezoelectric component 120 and the capacitor components 130 and 131, thereby improving frequency characteristics. In addition, unlike the related art, since the piezoelectric package does not need to dispose the capacitor components 130 and 131 on the substrate, the degree of freedom of the circuit design may be increased and the volume of the substrate may be reduced as much as the size of the capacitor components 130 and 131.

According to the exemplary embodiment of the present invention, since the piezoelectric package does not need to dispose the capacitor components on the main substrate unlike the related art, the degree of freedom of the circuit design may be increased and the volume of the main substrate may be reduced as much as the size of the capacitor components.

In addition, since the length of the signal line between the piezoelectric component and the capacitor components may be reduced, frequency characteristics may be significantly improved.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed exemplary embodiments. It is to be understood that other exemplary embodiments are also included within the spirit and scope of the appended claims.

What is claimed is:

1. A piezoelectric package comprising:
a body having a piezoelectric component mounted therein and having a lower surface electrode provided on a bottom surface thereof, the lower surface electrode being electrically connected to the piezoelectric component;
a groove part formed on the bottom surface of the body; and
a capacitor component provided in the groove part and electrically connected to the piezoelectric component.

2. The piezoelectric package according to claim 1, wherein the lower surface electrode is formed to surround one end portion of the groove part.

3. The piezoelectric package according to claim 1, further comprising a ground electrode provided on the bottom surface of the body and electrically connected to the capacitor component.

4. The piezoelectric package according to claim 3, wherein the ground electrode is formed to surround the other end portion of the groove part.

5. The piezoelectric package according to claim 3, wherein the capacitor component includes a pair of external terminals, one of the pair of external terminals being electrically connected to the lower surface electrode and the other being electrically connected to the ground electrode.

6. The piezoelectric package according to claim 1, wherein the body is configured of a base part, a lid covering an upper surface of the base part, and a bonding part provided at an outside edge part between the base part and the lid.

7. The piezoelectric package according to claim 6, wherein the base part is configured of a first base layer having the groove part formed therein and a second base layer including a connection part electrically connecting the piezoelectric component and the capacitor component to each other.

8. The piezoelectric package according to claim 7, wherein the connection part includes:
a first via penetrating through the second base layer; and
a first metal pattern having one end exposed to the outside through the groove part to be connected to the capacitor component and the other end connected to the first via.

9. The piezoelectric package according to claim 8, wherein the first via penetrates through up to the first base layer and is connected to the lower surface electrode.

10. The piezoelectric package according to claim 8, further comprising a first lead electrode formed across upper and lower surfaces and a side surface of the first base layer and having one end connected to the lower surface electrode and the other end connected to the first via.

11. The piezoelectric package according to claim 7, further comprising:
a ground electrode provided on the bottom surface of the body and electrically connected to the capacitor component;
a second metal pattern provided on a lower surface of the second base layer and having one end exposed to the outside through the groove part to be connected to the capacitor component; and
a second lead electrode formed across upper and lower surfaces and a side surface of the first base layer and having one end connected to the ground electrode and the other end connected to the second metal pattern.

12. The piezoelectric package according to claim 7, further comprising:
a ground electrode provided on the bottom surface of the body and electrically connected to the capacitor component;
a second metal pattern provided on a lower surface of the second base layer and having one end exposed to the outside through the groove part to be connected to the capacitor component; and
a second via penetrating through the first base layer and having one end connected to the ground electrode and the other end connected to the second metal pattern.

13. A piezoelectric package comprising:
a body having a piezoelectric component mounted therein and having a first lower surface electrode and a second lower surface electrode provided on a bottom surface thereof, the first lower surface electrode being electrically connected to an input terminal of the piezoelectric component and the second lower surface electrode being electrically connected to an output terminal of the piezoelectric component;
a first groove part and a second groove part formed on the bottom surface of the body;
a first capacitor component provided in the first groove part and electrically connected to the input terminal of the piezoelectric component; and
a second capacitor component provided in the second groove part and electrically connected to the output terminal of the piezoelectric component.

14. The piezoelectric package according to claim 13, further comprising a first ground electrode provided on the bottom surface of the body and electrically connected to the first capacitor component and a second ground electrode electrically connected to the second capacitor component.

15. The piezoelectric package according to claim 14, wherein the first and second lower surface electrodes and the first and second ground electrodes are each provided onto corner portions of the bottom surface of the body.

16. The piezoelectric package according to claim 14, wherein the first capacitor component includes a pair of external terminals, one of the pair of external terminals being electrically connected to the first lower surface electrode and the other being electrically connected to the first ground electrode.

17. The piezoelectric package according to claim 14, wherein the second capacitor component includes a pair of external terminals, one of the pair of external terminals being electrically connected to the second lower surface electrode and the other being electrically connected to the second ground electrode.

18. The piezoelectric package according to claim 14, wherein the first lower surface electrode and the first ground electrode, or the second lower surface electrode and the second ground electrode are provided to face each other in a shorter side direction of the body, and the first groove part is provided between the first lower surface electrode and the first ground electrode or the second groove part is provided between the second lower surface electrode and the second ground electrode.

19. The piezoelectric package according to claim 14, wherein the first lower surface electrode and the first ground electrode, or the second lower surface electrode and the second ground electrode are provided to face each other in a longer side direction of the body, and the first groove part is provided between the first lower surface electrode and the first ground electrode or the second groove part is provided between the second lower surface electrode and the second ground electrode.
